(19) United States
(12) Patent Application Publication
(10) Pub. No.: US 2005/0257891 A1
(43) Pub. Date: Nov. 24, 2005

(54) Plasma processing apparatus

(76) Inventors: Masashi Goto, Yokohama-shi (JP); Yukihiko Nakata, Nara-shi (JP)

Correspondence Address: GRAYBEAL, JACKSON, HALEY LLP, 155 - 108TH AVENUE NE, SUITE 350, BELLEVUE, WA, 98004-5901, US

(21) Appl. No.: 10/388,849

(22) Filed: Mar. 13, 2003

(30) Foreign Application Priority Data
Mar. 20, 2002 (JP) 2002-77979

(51) Int. Cl. C23C 16/00; C23F 1/00

(52) U.S. Cl. 156/345.41; 118/723 MW

(57) ABSTRACT

There is provided a plasma treatment apparatus capable of treating a square shaped substrate having a large area even in the case of using reactive plasma, the plasma treatment apparatus including a waveguide 1, a waveguide antenna 2 made up of slots provided on the H-surface of the waveguide 1, an electromagnetic wave radiation window 4 made of a dielectric, a dielectric space 10 sandwiched between the waveguide 2 and the electromagnetic wave radiation window 4, and generating plasma by using the electromagnetic wave radiated from the waveguide antenna 2 through the electromagnetic wave radiation window 4, wherein an uneven portion 11 is provided on the surface of the waveguide 1 opposite to the electromagnetic wave radiation window 4.

### BACKGROUND OF THE INVENTION

1. Field of the Invention

The present invention relates to a plasma treatment apparatus and, more particularly, to the apparatus capable of giving various plasma treatments such as treatments for film deposition, for improvement of surface quality or for etching, to a large scale square shaped substrate.

2. Prior Art

Heretofore, in the process of manufacturing a semiconductor device and a liquid crystal display, there have been used a diode parallel plate high frequency plasma treatment apparatus, an electron cyclotron resonance (ECR) plasma treatment apparatus and so forth, in order to carry out plasma treatment for film deposition, for surface quality improvement, or for etching.

However, the diode parallel plate plasma treatment apparatus carries such a problem that the plasma density is low while the electron temperature is high. On one hand, ECR plasma treatment apparatus also carries such a problem that the treatment over a large area becomes difficult because this apparatus requires a direct current magnetic field for plasma excitation.

Recently, however, in order to obviate such problems as mentioned above, there has been proposed a plasma treatment apparatus capable of generating the plasma with high density and low temperature electron without requiring any magnetic field for plasma excitation.

Such a plasma treatment apparatus as described above will be discussed in the following.

<<The First Prior Art Plasma Treatment Apparatus>>

FIG. 7(a) is a top view of the first prior art plasma treatment apparatus while FIG. 7(b) is a sectional view of the same.

This first prior art plasma treatment apparatus is described in the Japanese Patent No. 2,282,080.

In FIGS. 7(a) and 7(b), a reference numeral 71 indicates a coaxial transmission line; 72 a circular microwave radiation plate; 73 a plurality of slots coaxially provided on the circular microwave radiation plate 72; 74 a electromagnetic wave radiation window made of a dielectric; 75 a vacuum container; 76 a gas introduction system; 77 a gas exhaust system; 78 a substrate subject to the plasma treatment; and 79 a substrate mounting portion.

The microwave power is supplied to this plasma treatment apparatus from the coaxial transmission line 71 to the circular microwave radiation plate 72 having a plurality of slots 73 coaxially arranged thereon.

In this plasma treatment apparatus, the microwave introduced through the coaxial transmission line 71 toward the center of the circular microwave radiation plate 72 propagates in the radial direction of the circular microwave radiation plate 72, and then, it is radiated through the above plural slots 73, thereby uniform plasma being generated in the vacuum container 75.

<<The Second Prior Art Plasma Treatment Apparatus>>

FIG. 8(a) is a top view of the second prior art plasma treatment apparatus while FIG. 8(b) is a sectional view of the same.

The second prior art plasma treatment apparatus is described in detail by the Japanese Patent No. 2,858,090.

In FIGS. 8(a) and 8(b), a reference numeral 81 indicates a rectangular waveguide; 82 a waveguide antenna; 83 a microwave source; 84 a electromagnetic wave radiation window made of a dielectric; 85 a vacuum container; 86 a gas introduction system; 88 a gas exhaust system; 88 a substrate subject to the plasma treatment; 89 a substrate mount portion; 90 the reflecting face (short circuit face; a R-face) of the rectangular waveguide 81; and 91 the H-face of the rectangular waveguide 81 (the face vertical to the electric field direction of the microwave).

The microwave power is supplied to this plasma treatment apparatus through the electromagnetic wave radiation window 84 from the waveguide antenna 82 made up of slots arranged in a part of the H-face 91 of the rectangular waveguide 81, thereby plasma being generated in the vacuum container 85.

In this plasma treatment apparatus, the width (opening area) of slots constituting two waveguide antennas provided on the H-face 91 of the rectangular waveguide 81 is varied by taking account of the reflection at the reflecting face 90 of the rectangular waveguide 81, thereby equalizing the microwave radiation power radiated from the above slots. In FIG. 8(a), no indication is made as to the change in the width between the above slots, but it will be seen in the above-mentioned Japanese patent. For instance, the slot is formed in the step-like shape or a slope-like shape such that the width of slots becomes narrower toward the reflecting surface 90 of the rectangular waveguide 81.

With this, if the generated plasma is sufficiently diffused, it becomes possible to generate comparatively uniform plasma by means of the microwave power radiated from the above two slots.

Recently, the plasma treatment apparatus for use in the manufacture of semiconductor devices and liquid crystal displays has tendency to enlarge the scale of it keeping pace with the enlargement tendency of the substrate size. Especially, in case of plasma treatment apparatus for use in the manufacture of liquid crystal displays, the apparatus is required to have the ability capable of treating even a square shaped substrate of the class having a side of about one meter. The area of this substrate is equivalent to about ten times as wide as the substrate having a diameter of 300 mm as used most often in the manufacture of semiconductor devices.

Furthermore, in the plasma treatment, there are often used reactive gases for instance monosilane gas, oxygen gas, hydrogen gas, chloride gas and so forth, as raw material gases. As the plasma of these gases includes a large amount of negative ions (O—, H—, Cl—, etc.), there are greatly expected manufacturing facilities and methods which are achieved by taking account of the behavior of those negative ions.

In the above-mentioned first and second prior art plasma treatment apparatus, however, there still exist such problems to be solved as discussed in the following.

<<Problems in The First Prior Art Plasma Treatment Apparatus>>

As will be seen from the first prior art plasma treatment apparatus as shown in FIG. 7, if the microwave propagates through an electric conductor such as coaxial transmission line 71, the circular microwave radiation plate 72 and the like, there is caused a propagation loss due to the copper loss in the electric conductor. The higher the frequency becomes, the longer the coaxial transmission distance becomes, and also the larger the area of the radiation plate, the propagation loss becomes a more significant problem. Consequently, in case of the large scale plasma treatment apparatus designed for handling a very large substrate for use in the liquid crystal display and others, the microwave comes to largely attenuate, thus making it difficult to generate plasma with high efficiency.

Furthermore, the plasma treatment apparatus of the type in which the microwave is radiated from the circular microwave radiation plate 27, might be suitable for treating the circular substrate for use in the semiconductor device. However, in case of treating the square shaped substrate for use in the liquid crystal display there is caused such a problem that the plasma comes to lose its uniformity at corner portions of the substrate.

Accordingly, the first prior art plasma treatment apparatus carries such a problem that makes it difficult to treat the substrate having a large area, especially the square shaped substrate.

<<Problems in The Second Prior Art Plasma Treatment Apparatus>>

As will be seen from the second prior art plasma treatment apparatus as shown in FIG. 8, if the microwave propagates through the rectangular waveguide 81 and is radiated from two slots of the waveguide antenna 82, the above propagation loss can be suppressed to be low. However, in case of the reactive gas containing a large amount of negative ions in the generated plasma, as the bipolar diffusion coefficient of the plasma becomes small, there is caused such a problem that plasma comes to get together in the vicinity of the slots from which the microwave is radiated. The higher the pressure of the plasma becomes, this problem becomes serious. Therefore, it becomes difficult to carry out the plasma treatment over a large area substrate by using such a gas that generates negative ions with ease, for instance gas including oxygen, hydrogen, chloride and so forth, as a raw material gas, especially, difficult when the pressure of such gas is high.

Accordingly, an object of the invention is to solve the above-mentioned problems and to provide a plasma treatment apparatus capable of treating a large area substrate and a square shaped substrate even in case of the reactive plasma.

### SUMMARY OF THE INVENTION

In order to solve the above-mentioned problems, the invention takes such constitutions as recited in the scope of claim for patent attached to this specification.

A plasma treatment apparatus recited in claim 1 having a waveguide, a waveguide antenna 2 and an electromagnetic wave radiation window made of a dielectric, and generating plasma by using the electromagnetic wave radiated from the waveguide antenna through the electromagnetic wave radiation window, wherein an uneven portion is provided on the surface of the waveguide opposite to the electromagnetic wave radiation window. A plasma treatment apparatus recited in claim 2 wherein the size or the depth or the pitch of said uneven portion used in the plasma treatment apparatus recited in claim 1 is made larger than ⅛ of the wavelength of the microwave. A plasma treatment apparatus recited in claim 3 wherein the size or the depth or the pitch of said uneven portion used in the plasma treatment apparatus recited in claim 1 is made in order to improve the uniformity of said generating plasma.

A plasma treatment apparatus recited in claim 4 having a waveguide, a waveguide antenna and an electromagnetic wave radiation window made of a dielectric, and generating plasma by using the electromagnetic wave radiated from the waveguide antenna through the electromagnetic wave radiation window, wherein an uneven portion is provided on the surface of the electromagnetic wave radiation window opposing to the waveguide. A plasma treatment apparatus recited in claim 5 wherein the size or the depth or the pitch of said uneven portion used in the plasma treatment apparatus recited in claim 4 is made larger than ⅛ of the wavelength of the microwave. A plasma treatment apparatus recited in claim 6 wherein the size or the depth or the pitch of said uneven portion used in the plasma treatment apparatus recited in claim 4 is made in order to improve the uniformity of said generating plasma.

A plasma treatment apparatus recited in claim 7 having a waveguide, a waveguide antenna and an electromagnetic wave radiation window made of a dielectric, and generating plasma by using the electromagnetic wave radiated from the waveguide antenna through the electromagnetic wave radiation window, wherein the above electromagnetic wave radiation window is made of a mixture of the first member and at least one sort of the second member having a dielectric constant different form that of the first member.

A plasma treatment apparatus recited in claim 8 wherein the size of the second member used in the plasma treatment apparatus recited in claim 7 is larger than ⅛ of the wavelength of the microwave.

A plasma treatment apparatus recited in claim 9 having a waveguide, a waveguide antenna and an electromagnetic wave radiation window made of a dielectric, and a dielectric space sandwiched between the waveguide and the electromagnetic wave radiation window, and generating plasma by using the electromagnetic wave radiated from the waveguide antenna through the electromagnetic wave radiation window, wherein a mesh made of a conductive material is provided between the above dielectric space and the above electromagnetic wave radiation window.

A plasma treatment apparatus recited in claim 10, wherein the size of the above mesh used in the plasma treatment apparatus recited in claim 9 is made narrower under the above waveguide antenna and is made gradually wider according to the distance apart from the waveguide antenna.

A plasma treatment apparatus recited in claim 11 having a coaxial transmission line, an electromagnetic wave radiation plate, a plurality of openings provided on the electromagnetic wave radiation plate, and an electromagnetic wave radiation window made of a dielectric, and generating plasma by using the electromagnetic wave radiated from the coaxial transmission line through the electromagnetic wave radiation plate and the electromagnetic wave radiation window, wherein an uneven portion is provided on the surface of the electromagnetic wave radiation window opposite to the electromagnetic wave radiation plate.

A plasma treatment apparatus recited in claim 12 having a coaxial transmission line, an electromagnetic wave radiation plate, a plurality of openings provided on the electromagnetic wave radiation plate, and an electromagnetic wave radiation window made of a dielectric, and generating plasma by using the electromagnetic wave radiated from the coaxial transmission line through the electromagnetic wave radiation plate and the electromagnetic wave radiation window, wherein the above electromagnetic wave radiation window is made of a mixture of the first member and at least one sort of the second member having a dielectric constant different from that of the first member.

A plasma treatment apparatus recited in claim 13, wherein the size of the above second member used in the plasma treatment apparatus recited in claim 12 is made larger than ⅛ of the wavelength of the electromagnetic wave.

A plasma treatment apparatus recited in claim 14 having a coaxial transmission line, an electromagnetic wave radiation plate, a plurality of openings provided on the electromagnetic wave radiation plate, an electromagnetic wave radiation window made of a dielectric, and a dielectric space sandwiched between the electromagnetic wave radiation plate and the electromagnetic wave radiation window, and generating plasma by using the electromagnetic wave radiated from the coaxial transmission line through the electromagnetic wave radiation plate and the electromagnetic wave radiation window, wherein a mesh made of an electric conductive material is provided between the dielectric space and the electromagnetic wave radiation window.

A plasma treatment apparatus recited in claim 15, wherein the surface coming in contact with plasma of the electromagnetic wave radiation window used in the plasma treatment apparatus recited in claim 1, 2, 3, 4, 5, 6, 7, 8, 9, 10, 11, 12, 13, or 14, is a flat surface.

In a plasma treatment apparatus recited in claim 1, 2, 3, 4, 5, 6, 7, 8, 9, or 10, the waveguide is used for transmitting the electromagnetic wave and the electromagnetic wave power is radiated to the plasma from the waveguide antenna made up of a plurality of slots provided on the waveguide, thereby the electromagnetic wave with a large electric power being radiated efficiently.

Furthermore, in a plasma treatment apparatus recited in claim 1, 2, or 3, an uneven portion is provided on the surface of the waveguide opposite to the electromagnetic wave radiation window. The electromagnetic wave is reflected and scattered by the uneven portion to be well dispersed, thereby the radiation intensity of the electromagnetic wave being equalized.

Still further, in a plasma treatment apparatus recited in claim 4, 5 or 6, the uneven portion is provided on the surface of the electromagnetic wave radiation window opposite to the waveguide instead of providing it on the side of the waveguide. With this, the electromagnetic wave is similarly reflected and scattered by the uneven portion to be well dispersed, thereby the radiation intensity of the electromagnetic wave being equalized.

Still further, in a plasma treatment apparatus recited in claim 7, the electromagnetic wave radiation window is made of a mixture of the first member and at least one sort of the second member having a dielectric constant different from that of the first member and mixed with the first member. With this, the electromagnetic wave is reflected and scattered by the second member to be well dispersed. With this, the radiation intensity of the electromagnetic wave can be equalized.

Still further, in a plasma treatment apparatus recited in claim 8, the size of the second member mixed in the electromagnetic wave radiation window is made larger than ⅛ of the wavelength of the electromagnetic wave. With this, the electromagnetic wave is reflected and scattered by the second member to be efficiently dispersed and the radiation intensity of the electromagnetic wave can be equalized.

Still further, in a plasma treatment apparatus recited in claim 9, a mesh made of an electric conductive material is provided between the dielectric space and the electromagnetic wave radiation window. With this, the electromagnetic wave is reflected and scattered by the mesh to be dispersed and the radiation intensity of the electromagnetic wave can be equalized.

Still further, in a plasma treatment apparatus recited in claim 10, the size of the above mesh is made narrower under the above waveguide antenna 2 and is made gradually wider according to the distance apart from the waveguide antenna. With this, the electromagnetic wave is reflected and scattered by the mesh to be dispersed. Thus, the radiation intensity of the electromagnetic wave can be more equalized.

Still further, in a plasma treatment apparatus recited in claim 11, an uneven portion is provided on the surface of the electromagnetic wave radiation window opposite to the electromagnetic wave radiation plate. With this, the electromagnetic wave is reflected and scattered by the uneven portion to be dispersed. Thus, the radiation intensity of the electromagnetic wave can be equalized.

Still further, in a plasma treatment apparatus recited in claim 12, the electromagnetic wave radiation window is made of a mixture of the first member and at least one sort of the second member having a dielectric constant different from that of the first member. With this, the electromagnetic wave is reflected and scattered by the second member to be well dispersed. With this, the radiation intensity of the electromagnetic wave can be equalized.

Still further, in a plasma treatment apparatus recited in claim 13, the size of the second member mixed in the electromagnetic wave radiation window is made larger than ⅛ of the wavelength of the microwave. With this, the electromagnetic wave is reflected and scattered by the second member to be efficiently dispersed. Thus, the radiation intensity of the electromagnetic wave can be equalized.

Still further, in a plasma treatment apparatus recited in claim 14, a mesh made of an electric conductive material is provided between the dielectric space and the electromagnetic wave radiation window. With this, the electromagnetic wave is reflected and scattered by the mesh to be well dispersed. Thus, the radiation intensity of the electromagnetic wave can be equalized.

Still further, in a plasma treatment apparatus recited in claim 15, 16, 17, 18, 19, 20, 21, 22, 23, 24, 25, 26, 27, or 28, the surface in contact with plasma of the electromagnetic wave radiation window is kept flat. With this, it can be prevented that the film rest and particles take place in the process of film formation and etching.

In the following, the invention will be described in detail with reference to the accompanying drawings in which constituents of the invention having like function are designated by like reference numerals and signs, and repetitive description thereof will be omitted for simplification.

### BRIEF DESCRIPTION OF THE DRAWINGS

FIG. 1(a) is a top view of the first embodiment of a plasma treatment apparatus according to the invention while FIG. 1(b) is a sectional view of the same.

FIG. 2(a) is a top view of the second embodiment of a plasma treatment apparatus according to the invention while FIG. 2(b) is a sectional view of the same.

FIG. 3(a) is a top view of the electromagnetic wave radiation window in the third embodiment of a plasma treatment apparatus according to the invention while FIG. 3(b) is a sectional view of the same.

FIG. 4(a) is a top view of the electromagnetic wave radiation window in the third embodiment of a plasma treatment apparatus according to the invention while FIG. 4(b) is a sectional view of the same.

FIG. 5(a) is a top view of the fourth embodiment of a plasma treatment apparatus according to the invention while FIG. 5(b) is a sectional view of the same.

FIG. 6(a) is a top view of the fifth embodiment of a plasma treatment apparatus according to the invention while FIG. 6(b) is a sectional view of the same.

FIG. 7(a) is a top view of the first prior art plasma treatment apparatus while FIG. 7(b) is a sectional view of the same.

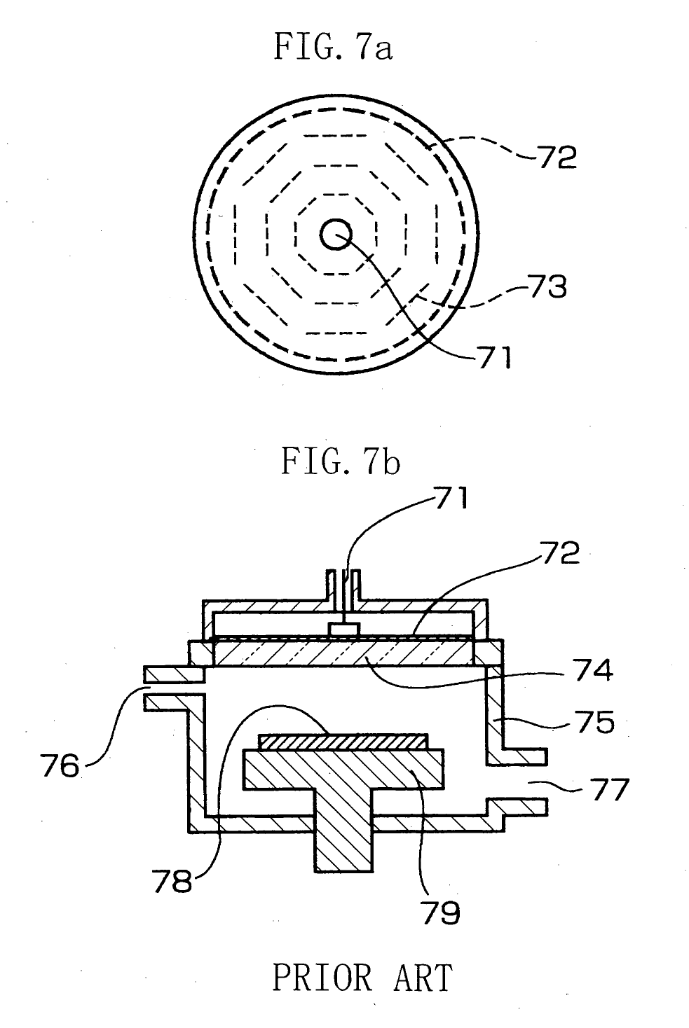

FIG. 8(a) is a top view of the second prior art plasma treatment apparatus according while FIG. 8(b) is a sectional view of the same.

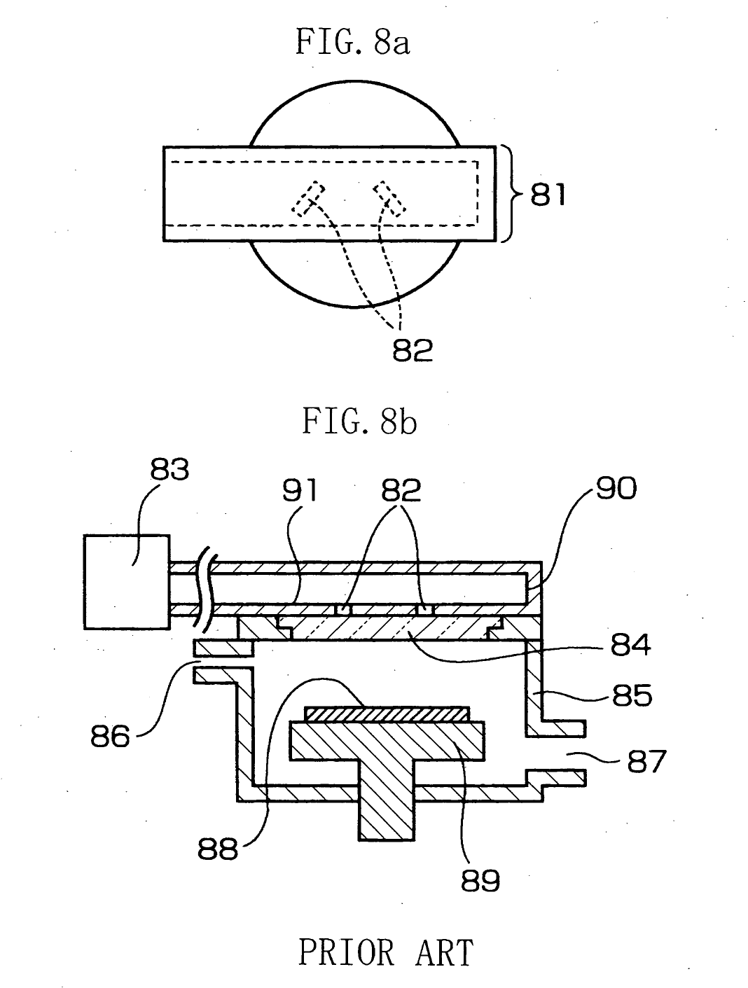

### DETAILED DESCRIPTION OF THE PREFERRED EMBODIMENTS

### First Embodiment

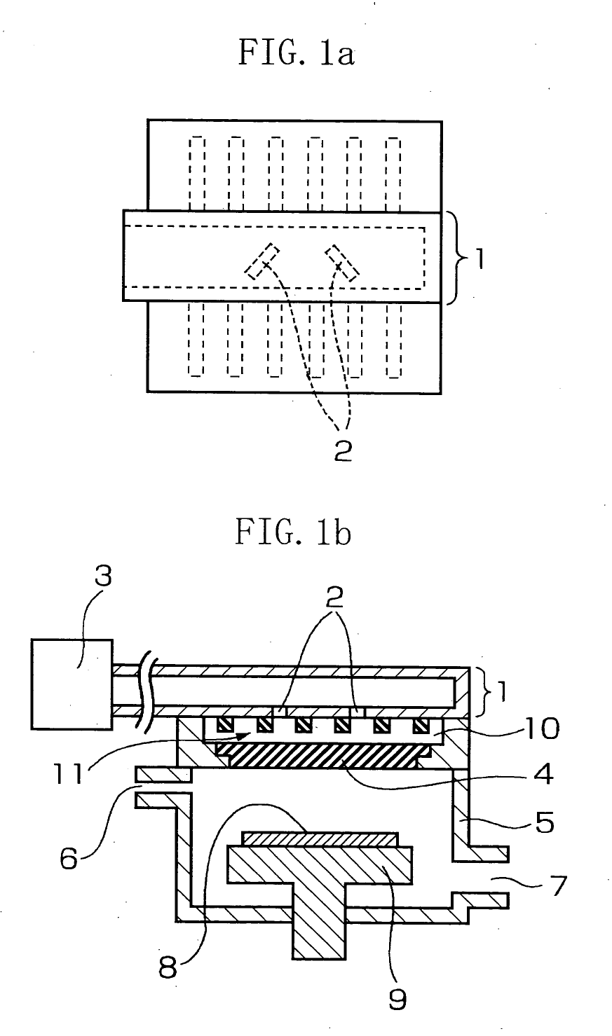

FIG. 1(a) is a top view of the first embodiment of the plasma treatment apparatus according to the invention while FIG. 1(b) is a sectional view of the same.

Referring to FIGS. 1(a) and 1(b), a reference numeral 1 indicates a rectangular waveguide; 2 a waveguide antenna; 3 an electromagnetic wave source for instance a microwave source; 4 an electromagnetic wave radiation window (electromagnetic wave introduction window) made up of a dielectric such as quartz, glass, ceramics and so on; 5 a vacuum container; 6 a gas introduction system; 7 a gas exhaust system; 8 a substrate subject to plasma treatment; 9 a substrate mount portion; 10 a dielectric space (air space) sandwiched between the waveguide antenna 2 and the electromagnetic wave window 4; and 11 an uneven portion provided so as to oppose to the electromagnetic wave radiation window 4 of the waveguide 1.

The vacuum container 5 in which the plasma is generated, is connected with the gas introduction system 6 for introducing the raw material gas as well as with the gas exhaust system 7 for exhausting the introduced gas.

The microwave oscillated by the oscillator of the microwave source 3 is transmitted through the waveguide 1 and then radiated from the waveguide antenna into the vacuum container 5 through the electromagnetic wave radiation window 4.

In the first embodiment, a plurality of thin elongated projection portions having a width of 10 mm and a height of 5 mm are aligned at an interval of 30 mm on the surface having the waveguide antenna 2 of the waveguide 1 and opposing to the electromagnetic wave radiation window 4. With this, an uneven portion 11 is constituted.

The electromagnetic wave radiation window 4 is set up at a distance of 5 mm from the projection portion of the uneven portion 11 of the wave guide 1. Both surfaces of the electromagnetic wave radiation window 4 have a flat surface and are set up such that one of them faces to the waveguide 1 while the other comes in contact with the plasma.

The microwave radiated from the waveguide antenna 2 repeats reflecting and scattering between the uneven portion 11 and plasma to be dispersed in a wide range. At this time, the region between the waveguide antenna 2 and plasma acts as if it were a dummy cavity resonator. This is because the plasma acts as a metal wall against the electromagnetic wave, if the plasma density is high. The condition for the plasma to act as the metal wall is that the plasma frequency (wp) is higher than the frequency (w) of the radiated electromagnetic wave.

In the inside of this dummy resonator, the highly dispersed wave is generated with the effect of the uneven portion 11 provided in the waveguide 1, and uniformity in the electromagnetic wave radiation strength can be enhanced comparing with the case where no uneven portion 11 is provided.

The shape of the projection portion constituting the uneven portion 11 provided in the waveguide 1 is not limited to that which is adopted in the first embodiment, that is, the constitution made up of a plurality of prism-like (square pillar-like) projections arranged in parallel. For instance, the uneven portion 11 may be made up of a large number of columnar, pyramid-like, or conic projections which are two-dimensionally arrange.

The desirable size or depth or pitch of said uneven portion is larger than ⅛ of the wavelength of the microwave to disperse the plasma in wide range. The waveguide antenna 2 consists of slots and conductor in a bottom part of waveguide 1. Also, each opening on the waveguide antenna may take a shape of not only a rectangular slot, but also a circular, an oval and any other shape. The first embodiment corresponds to claim 1, 2, or 3, which recites a plasma treatment apparatus having a waveguide 1, a waveguide antenna 2 and an electromagnetic wave radiation window 4 made of a dielectric, and generating plasma by using the electromagnetic wave radiated from the waveguide antenna 2 through the electromagnetic wave radiation window 4, wherein there is provided an uneven portion 11 which is provided on the surface of the waveguide 1 opposite to the electromagnetic wave radiation window 4.

The first embodiment also corresponds to claim 15, 16, or 17, which recites that the surface in contact with plasma of the electromagnetic wave radiation window 4 is a flat surface. Furthermore, claim 15, 16, or 17 corresponds not only to the first embodiment but also to all the second through fifth embodiments which will be described in the following.

### Second Embodiment

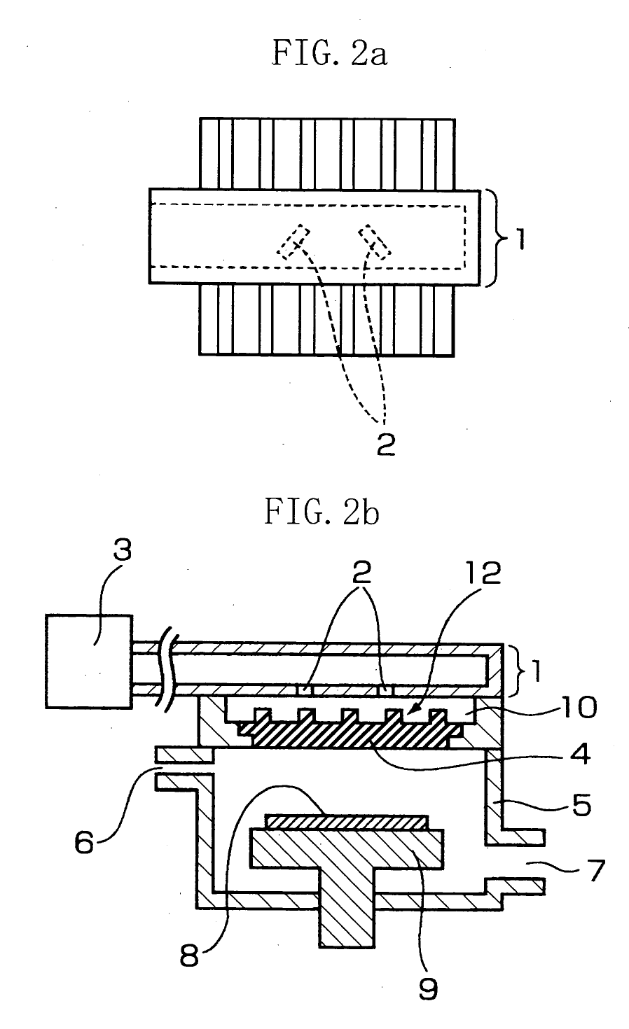

FIG. 2(a) is a top view of the second embodiment of the plasma treatment apparatus according to the invention while FIG. 2(b) is a sectional view of the same.

In FIGS. 2(a) and 2(b), a reference numeral 12 indicates an uneven portion which is provided on the surface of the electromagnetic wave radiation window 4 opposite to the waveguide 1.

In the second embodiment, a plurality of thin elongated projection portions having a width of 10 mm and a height of 5 mm are aligned at an interval of 30 mm on the surface of the electromagnetic wave radiation window 4 opposing to the waveguide 1. With this, an uneven portion 12 is constituted.

The projection portion of the uneven portion 12 of the electromagnetic wave radiation window 4 is set up at a distance of 5 mm from the outside surface of the waveguide 1 on which the waveguide antenna 2 is provided. The other surface of the electromagnetic wave radiation window 4 having no uneven portion 12 but coming in contact with the plasma is a flat surface.

In the second embodiment, similar to the case of the first embodiment, the microwave radiated from the waveguide antenna 2 repeats reflecting and scattering due to the uneven portion 12 provided between the waveguide antenna 2 and plasma to be dispersed in a wide range. At this time, the region between the waveguide antenna 2 and plasma acts as if it were a dummy cavity resonator. This is because the plasma acts as a metal wall against the electromagnetic wave, if the plasma density is high. The condition for the plasma to act as the metal wall is that the plasma frequency (ωp) is higher than the frequency (ω) of the radiated electromagnetic wave.

In this dummy resonator, the highly dispersible wave is generated with the effect of the uneven portion 12 provided in the waveguide 1, and uniformity in the electromagnetic wave radiation strength can be enhanced comparing with the case where no uneven portion 12 is provided.

The shape of the projection portion constituting the uneven portion 12 provided in the electromagnetic wave radiation window 4 is not limited to that which is adopted in the second embodiment, that is, the constitution made up of a plurality of prism-like (square pillar-like) projections aligned in parallel. For instance, the uneven portion 12 may be made up of a large number of columnar, pyramid-like, or conic projections which are two-dimensionally arrange.

The second embodiment corresponds to claim 4, 5, or 6, which recites a plasma treatment apparatus having a waveguide 1, a waveguide antenna 2 and an electromagnetic wave radiation window 4 made of a dielectric, and generating plasma by using the electromagnetic wave radiated from the waveguide antenna 2 through the electromagnetic wave radiation window 4, wherein there is provided an uneven portion 12 which is provided on the surface of the electromagnetic wave radiation window 4 opposing to the above waveguide.

### Third Embodiment

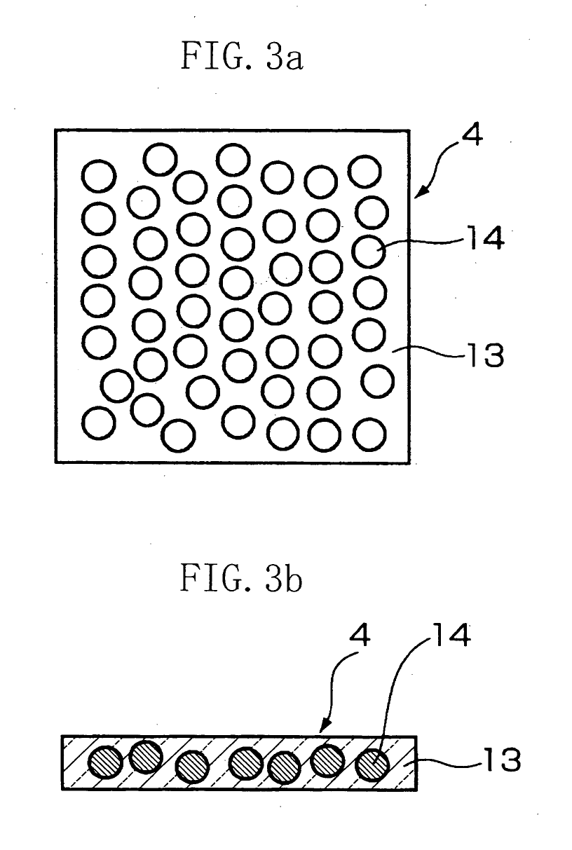

FIG. 3(a) is a top view of the second embodiment of the plasma treatment apparatus according to the invention while FIG. 3(b) is a sectional view of the same.

In FIGS. 3(a) and 3(b), a reference numeral 13 indicates a glass plate constituting an electromagnetic wave radiation window 4 and 14 a mixing member made of spherical ceramics mixed to the glass plate 13.

In the third embodiment, the electromagnetic wave radiation window 4 is made of the glass plate (dielectric constant: 4.7) 13 mixed with the mixing member 14 such as ceramics for instance alumina (dielectric constant: 9) and so on.

For instance the diameter of the spherical mixing member 14 is 2.5 cm while the thickness of the electromagnetic wave radiation window 4 is 5 cm. The diameter of the mixing member 14 is made larger than ⅛ of the wavelength of the microwave. With this, it becomes possible to efficiently disperse the microwave by reflecting and scattering it. Like this, if there is used the electromagnetic wave radiation window 4 mixed with the mixing member 14 having a different dielectric constant, the uniformity of plasma is enhanced comparing with the electromagnetic wave radiation window 4 formed of a glass made of a single material.

Of course, it would be apparent that the effect of the invention is not limited to the use of the above-mentioned ceramics as the mixing member 14 having a different dielectric constant. It is possible to select a material having a desirable dielectric constant for instance sapphire, aluminum nitride, zirconia and so forth. Furthermore, there is no need for the quality of mixing member 14 to be unified and it may be allowed that the mixing member 14 is a mixture of materials having different qualities.

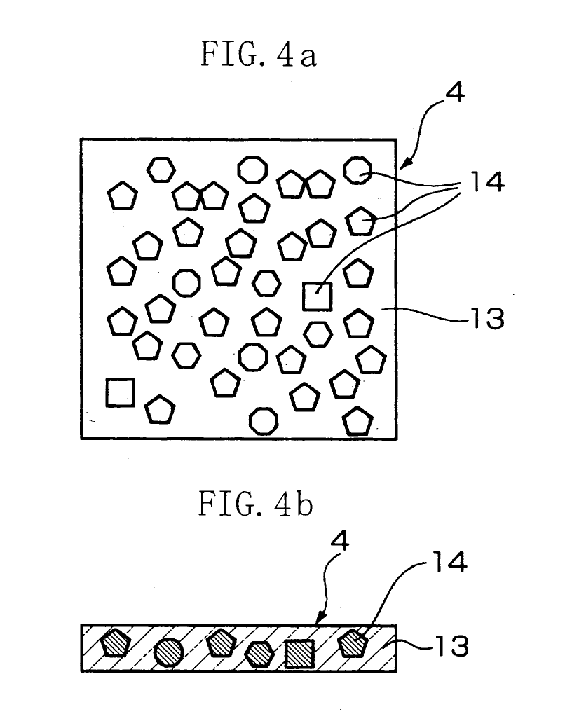

FIG. 4(a) is a top view of the electromagnetic wave radiation window 4 having a different constitution in the third embodiment of a plasma treatment apparatus according to the invention while FIG. 4(b) is a sectional view of the same.

In FIG. 3, the spherical mixing member 14 is used as the mixing member mixed with the glass plate 13 constituting the electromagnetic wave radiation window 4. As shown in FIGS. 4(a) and 4(b), however, the shape of the mixing member 14 is not limited to the spherical shape, and it possible to use the mixing member 14 having various shapes for instance a cubic and so on to further enhance the dispersion of the microwave.

The third embodiment corresponds to claim 7, which recites a plasma treatment apparatus having a waveguide 1, a waveguide antenna 2 and an electromagnetic wave radiation window 4 made of a dielectric, and generating plasma by using the electromagnetic wave radiated from the waveguide antenna 2 through the electromagnetic wave radiation window 4, wherein the above electromagnetic wave radiation window 4 is formed by mixing the first member (glass plate 13) with at least one sort of the second member (mixing member 14) having a dielectric constant different form that of the first member.

Furthermore, the third embodiment also corresponds to claim 8, which recites that the size of the second member (mixing member 14) is larger than ⅛ of the wavelength of the microwave.

### Forth Embodiment

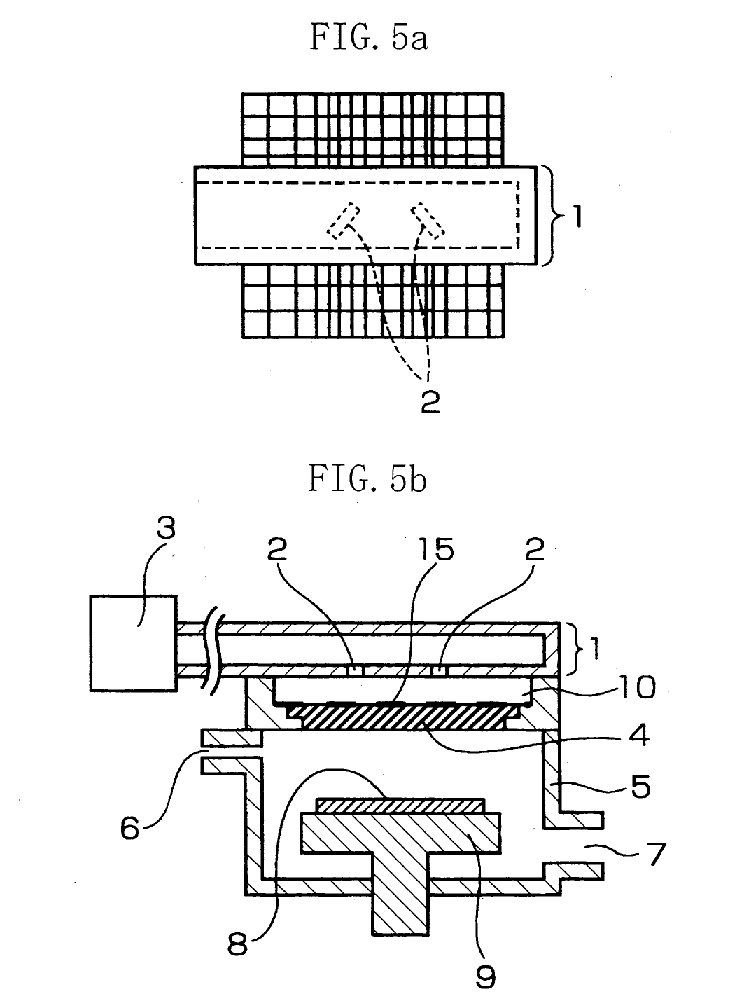

FIG. 5(a) is a top view of the fourth embodiment of the plasma treatment apparatus according to the invention while FIG. 5(b) is a sectional view of the same.

In FIGS. 5(a) and 5(b), a reference numeral 15 indicates a mesh made of a conductive material and provided between a dielectric space 10 and the electromagnetic wave radiation window 4.

In the fourth embodiment, the conductive mesh 15 made of a stainless steel is provided between the dielectric space filled with air and the electromagnetic wave radiation window 4 made of quartz, preferably provided on the upper surface of the electromagnetic wave radiation window 4.

With regard to the size of the mesh 15, it is enough if the mesh 15 has such a size (opening size) that a part of the microwave can pass through it. Accordingly, it is preferable that the maximum mesh size is ⅛ or less of the wavelength of the microwave. In the fourth embodiment, the mesh 15 is made narrower at the portion corresponding to the opening (slot) of the waveguide antenna 2 and is made gradually wider according to the distance apart therefrom. In this embodiment, the mesh 15 has an opening of 0.8 cm square at the narrowest portion and of 1.5 cm square at the widest portion.

With provision of the mesh like this, the microwave is reflected, scattered and dispersed, thereby the radiation strength of the microwave being equalized.

Each material used for forming the above-mentioned dielectric space 10, dielectric wave radiation window 4 and conductive mesh 15 is not limited to that which is used in the fourth embodiment. Various materials may be used, if they have like quality and can take effect of the invention.

The opening size of the mesh 15 is not limited to the above-mentioned value. It is enough for the mesh 15 to have an opening size allowing at least a part of the microwave to pass through it.

The fourth embodiment corresponds to claim 9, which recites a plasma treatment apparatus having a waveguide 1, a waveguide antenna 2 and an electromagnetic wave radiation window 4 made of a dielectric, a dielectric space 10 sandwiched between the waveguide 2 and the electromagnetic wave radiation window 4, and generating plasma by using the electromagnetic wave radiated from the waveguide antenna 2 through the electromagnetic wave radiation window 4, wherein a mesh made of a conductive material is provided between the above dielectric space 10 and the above electromagnetic wave radiation window 4.

The fourth embodiment corresponds to claim 10, which recites that the size of the above mesh 15 is made narrower under the above waveguide antenna 2 and is made gradually wider according to the distance apart from the waveguide antenna.

### Fifth Embodiment

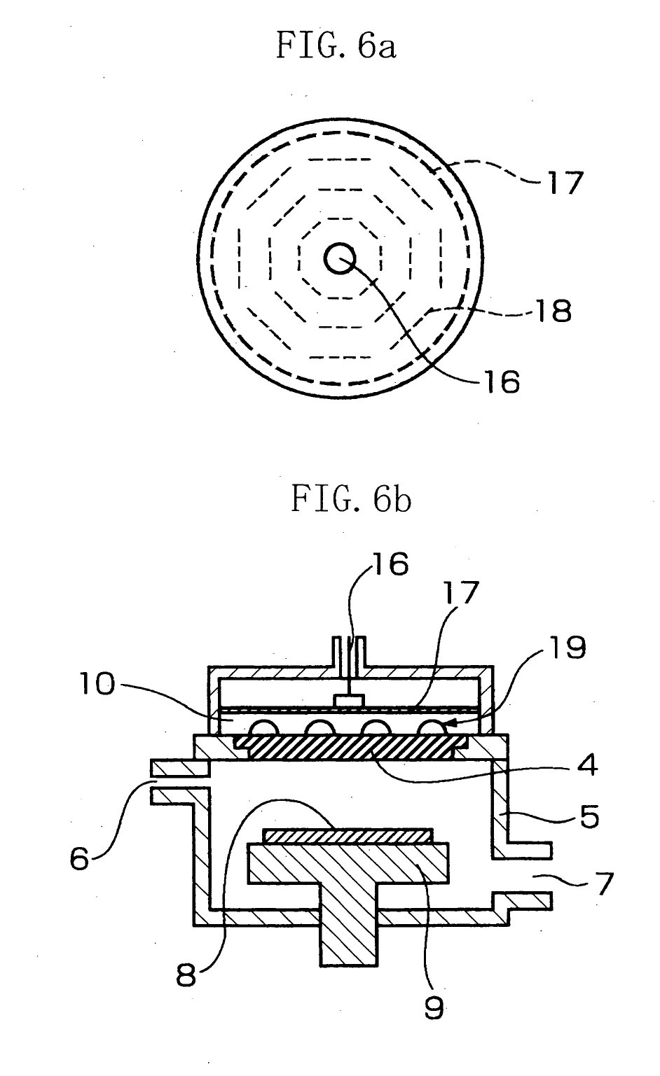

FIG. 6(a) is a top view of the fifth embodiment of a plasma treatment apparatus according to the invention while FIG. 6(b) is a sectional view of the same.

Referring to FIGS. 6(a) and 6(b), a reference numeral 16 indicates a coaxial transmission line; 17 a circular microwave radiation plate; 18 a plurality of slots a plurality of slots coaxially formed in the circular microwave radiation plate 17; and 19 an uneven portion having semispherical projection portions which are provided in the electromagnetic wave radiation window 4.

The fifth embodiment relates a plasma treatment apparatus to which the circular microwave power is supplied from the coaxial transmission line 16.

In the fifth embodiment, the microwave introduced toward the center of the circular microwave radiation plate 17 from the coaxial transmission line 16 propagates in the radial direction of the circular microwave radiation plate 17 and is radiated from slots 18 provided on the circular microwave radiation plate 17 into the vacuum container 5 through the electromagnetic wave radiation window 4 made of a dielectric material such as quartz, glass, ceramics and so forth.

In the fifth embodiment, the uneven portion 19 made up of a plurality of semicircular projection portions having a radius of 3 cm is provided on one surface of the electromagnetic wave radiation window 4 opposite to the circular microwave radiation plate 17. The projection portion of the uneven portion 19 of the electromagnetic wave radiation window 4 is set up at a distance of 5 mm from the circular microwave radiation plate 17. The other surface of the electromagnetic wave radiation window 4 is flat and comes in contact with plasma.

The microwave radiated from slots 18 of the circular microwave radiation plate 17 is reflected and scattered by the uneven portion 19 of the electromagnetic wave radiation window 4 provided between the circular microwave radiation plate 17 and plasma, thereby being dispersed in a wide range. At this time, the region between the circular microwave radiation plate 17 and plasma acts as if it were a dummy cavity resonator. This is because the plasma acts as a metal wall against the electromagnetic wave, if the plasma density is high. The condition for the plasma to act as the metal wall is that the plasma frequency (ωp) is higher than the frequency (ω) of the radiated electromagnetic wave.

In the inside of this dummy resonator, the highly dispersed wave is generated with the effect of the uneven portion 19 provided on the one surface of the electromagnetic wave radiation window 4, and uniformity in the electromagnetic wave radiation strength can be enhanced comparing with the case where no uneven portion 11 is provided.

The shape and arrangement of the projection portion in the uneven portion 19 provided on the surface of the electromagnetic wave radiation window 4 is not limited to those which are adopted in the fifth embodiment wherein the uneven portion 19 is made up of a plurality of semicircular projection portions arranged two-dimensionally. For instance, the uneven portion 19 may be made up of a plurality of prism-like (square pillar-like) projections arranged in parallel as described in the second embodiment, or a plurality of semicircular pillar-like projections arranged in parallel, or a large number of circular column-like projections, pyramid-like projections, or conic-like projections each of which is two-dimensionally arranged.

The fifth embodiment corresponds to claim 11, which recites a plasma treatment apparatus having a coaxial transmission line 16, an electromagnetic wave radiation plate 17, a plurality of openings (slots 18) provided on the electromagnetic wave radiation plate 17, and an electromagnetic wave radiation window 4 made of a dielectric, and generating plasma by using the electromagnetic wave radiated from the coaxial transmission line 16 through the electromagnetic wave radiation plate 17 and the electromagnetic wave radiation window 4, wherein an uneven portion is provided on the surface of the electromagnetic wave radiation window 4 opposite to the electromagnetic wave radiation plate 17.

It is possible for the plasma treatment apparatus according to the fifth embodiment, to which the circular microwave power is supplied from the coaxial transmission line 16, to use, instead of providing the uneven portion 19, the electromagnetic wave radiation window 4 including a mixing member 14 of which the dielectric constant is different from that of the basic material of the window 4 (corres. to claim 12) as shown in FIGS. 3(a) and 3(b) and FIGS. 4(a) and 4(b) referred in the third embodiment; to make the diameter of the mixing member 14 larger than ⅛ of the wavelength of the microwave as described in the third embodiment (corres. to claim 13); and also to set up a conductive mesh 15 on the electromagnetic wave radiation window 4 (corres. to claim 14) as described in the fourth embodiment as shown in FIGS. 5(a) and 5(b). With this, it is needless to say the effect of the invention can be obtained. Furthermore, it is possible to properly combine the first through fifth embodiments according to the invention.

As describe in the above, in the plasma treatment apparatus according to the first through fourth embodiments, as the dummy cavity resonator sufficiently disperses the microwave, it becomes possible to reduce the number of the openings (slots) between the waveguide antenna 2 and plasma, thus the design of the antenna becoming easier. Furthermore, as it becomes possible for the dummy cavity resonator to radiate the electromagnetic wave in a wider range than the antenna 2, plasma can be generated to cover a large area. Still further, in the plasma treatment apparatus according to the first through fifth embodiments, as the strength of the electromagnetic wave radiated against plasma is equalized and at the same time, it becomes possible to radiate the electromagnetic wave in a wider range, it becomes possible to generate plasma covering a large area. Still further, in the plasma treatment apparatus according to the second and fifth embodiments, as the uneven portion 12 or 19 for use in dispersion of the microwave is provided on the one side surface of the electromagnetic wave radiation window 4 opposite to the waveguide 1 or to the circular microwave radiation plate 17, the other side surface exposed to plasma of the electromagnetic wave radiation window 4 is flat while the uneven portion 12 or 19 is never exposed to plasma. With this, the surface exposed to plasma of the electromagnetic wave radiation window 4 can be prevented from occurrence of the film rest and particles

While some embodiments of the invention have been shown and described in the above with reference to the accompanying drawings, the invention is not limited to such embodiment. Various changes and modifications will be possible without departing from the gist of the invention.

As has been explained so far, according to the invention, there is provided a plasma treatment apparatus capable of treating a substrate with a large area as well as a substrate of the square shaped even in the case of using reactive plasma.

1. A plasma processing apparatus comprising:
an electromagnetic wave source;
one of a waveguide or a coaxial transmission line for transmitting an electromagnetic wave from said electromagnetic wave source;
a vacuum container operatively coupled to said waveguide or coaxial transmission line to expose said electromagnetic wave to a dielectric space and in which a plasma generated by said electromagnetic wave radiated within said vacuum container; and
scattering means for scattering the electromagnetic wave radiated within said dielectric space.

2. A plasma treatment apparatus as claimed in claim 1, wherein the size or the depth or the pitch of said uneven portion is made larger than ⅛ of the wavelength of the microwave.

3. A plasma treatment apparatus as claimed in claim 1, wherein the size or the depth or the pitch of said uneven portion is made in order to improve the uniformity of said generating plasma.

4. A plasma treatment apparatus having a waveguide, a waveguide antenna and an electromagnetic wave radiation window made of a dielectric, and generating plasma by using the electromagnetic wave radiated from said waveguide antenna through said electromagnetic wave radiation window,
wherein an uneven portion is provided on the surface of said electromagnetic wave radiation window opposite to said waveguide.

5. A plasma treatment apparatus as claimed in claim 4, wherein the size or the depth or the pitch of said uneven portion is made larger than ⅛ of the wavelength of the microwave.

6. A plasma treatment apparatus as claimed in claim 4, wherein the size or the depth or the pitch of said uneven portion is made in order to improve the uniformity of said generating plasma.

7. A plasma treatment apparatus having a waveguide, a waveguide antenna and an electromagnetic wave radiation window made of a dielectric, and generating plasma by using the electromagnetic wave radiated from said waveguide antenna through said electromagnetic wave radiation window,
wherein said electromagnetic wave radiation window is made of a mixture of the first member and at least one sort of the second member having a dielectric constant different form that of the first member.

8. A plasma treatment apparatus as claimed in claim 7, wherein the size of said second member is made larger than ⅛ of the wavelength of the microwave.

9. A plasma treatment apparatus having a waveguide, a waveguide antenna, an electromagnetic wave radiation window made of a dielectric, and generating plasma by using the electromagnetic wave radiated from said waveguide antenna through said electromagnetic wave radiation window,
wherein a mesh made of a conductive material is provided between said waveguide antenna and said electromagnetic wave radiation window.

10. A plasma treatment apparatus as claimed in claim 9, wherein the size of said mesh is made narrower under said waveguide antenna and is made gradually wider according to the distance apart from said waveguide antenna.

11. A plasma treatment apparatus having a coaxial transmission line, an electromagnetic wave radiation plate with a plurality of openings, and an electromagnetic wave radiation window made of a dielectric, and generating plasma by using said electromagnetic wave radiated from said electromagnetic wave radiation plate through said electromagnetic wave radiation window by said coaxial transmission line,
wherein an uneven portion is provided on the surface of said electromagnetic wave radiation window opposite to said electromagnetic wave radiation plate.

12. A plasma treatment apparatus having a coaxial transmission line, an electromagnetic wave radiation plate with a plurality of openings, and an electromagnetic wave radiation window made of a dielectric, and generating plasma by using the electromagnetic wave radiated from said electromagnetic wave radiation plate through said electromagnetic wave radiation window by said coaxial transmission line,
wherein said electromagnetic wave radiation window is made of a mixture of the first member and at least one sort of the second member having a dielectric constant different from that said first member.

13. A plasma treatment apparatus as claimed in claim 12, wherein the size of said second member is made larger than ⅛ of the wavelength of said electromagnetic wave.

14. A plasma treatment apparatus having a coaxial transmission line, an electromagnetic wave radiation plate with a plurality of openings, an electromagnetic wave radiation window made of a dielectric, and generating plasma by using the electromagnetic wave radiated from said electromagnetic wave radiation plate through said electromagnetic wave radiation window by said coaxial transmission line,
wherein a mesh made of an electric conductive material is provided between a waveguide antenna and said electromagnetic wave radiation window.

15. A plasma treatment apparatus as claimed in claim 1, wherein the surface of said electromagnetic wave radiation window coming in contact with said plasma is a flat surface.

16. A plasma treatment apparatus as claimed in claim 2, wherein the surface of said electromagnetic wave radiation window coming in contact with said plasma is a flat surface.

17. A plasma treatment apparatus as claimed in claim 3, wherein the surface of said electromagnetic wave radiation window coming in contact with said plasma is a flat surface.

18. A plasma treatment apparatus as claimed in claim 4, wherein the surface of said electromagnetic wave radiation window coming in contact with said plasma is a flat surface.

19. A plasma treatment apparatus as claimed in claim 5, wherein the surface of said electromagnetic wave radiation window coming in contact with said plasma is a flat surface.

20. A plasma treatment apparatus as claimed in claim 6, wherein the surface of said electromagnetic wave radiation window coming in contact with said plasma is a flat surface.

21. A plasma treatment apparatus as claimed in claim 7, wherein the surface of said electromagnetic wave radiation window coming in contact with said plasma is a flat surface.

22. A plasma treatment apparatus as claimed in claim 8, wherein the surface of said electromagnetic wave radiation window coming in contact with said plasma is a flat surface.

23. A plasma treatment apparatus as claimed in claim 9, wherein the surface of said electromagnetic wave radiation window coming in contact with said plasma is a flat surface.

24. A plasma treatment apparatus as claimed in claim 10, wherein the surface of said electromagnetic wave radiation window coming in contact with said plasma is a flat surface.

25. A plasma treatment apparatus as claimed in claim 11, wherein the surface of said electromagnetic wave radiation window coming in contact with said plasma is a flat surface.

26. A plasma treatment apparatus as claimed in claim 12, wherein the surface of said electromagnetic wave radiation window coming in contact with said plasma is a flat surface.

27. A plasma treatment apparatus as claimed in claim 13, wherein the surface of said electromagnetic wave radiation window coming in contact with said plasma is a flat surface.

28. A plasma treatment apparatus as claimed in claim 14, wherein the surface of said electromagnetic wave radiation window coming in contact with said plasma is a flat surface.
